(19) United States
(12) Patent Application Publication
(10) Pub. No.: US 2009/0114939 A1
(43) Pub. Date: May 7, 2009

(54) ILLUMINATION SYSTEM COMPRISING A RADIATION SOURCE AND A LUMINESCENT MATERIAL

(75) Inventors: Peter Schmidt, Aachen (DE); Walter Mayr, Alsdorf (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/298,144

(22) PCT Filed: Apr. 17, 2007
(86) PCT No.: PCT/IB2007/051368

§ 371 Date: Oct. 23, 2008

(30) Foreign Application Priority Data
Apr. 27, 2006 (EP) 06113235.3

(51) Int. Cl. H01L 33/00; C09K 11/54; C09K 11/71

(52) U.S. Cl. 257/98; 252/301.6 P; 252/301.4 P; 257/E33.055

(57) ABSTRACT

An illumination system, comprising a radiation source and a luminescent material comprising at least one phosphor capable of absorbing a part of the light emitted by the radiation source and emitting light having a wavelength different from that of the absorbed light; wherein said at least one phosphor is a yellow to red-emitting europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1 can provide light sources having high luminosity and color-rendering index, especially in conjunction with a light emitting diode as a radiation source. The red to yellow emitting europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1 is efficiently excitable by primary radiation in the near UV-to-blue range of the electromagnetic spectrum.

### BACKGROUND OF THE INVENTION

The present invention generally relates to an illumination system comprising a radiation source and a luminescent material comprising a phosphor. The invention also relates to a phosphor for use in such an illumination system.

More particularly, the invention relates to an illumination system and luminescent material comprising a phosphor for the generation of specific, colored light, including white light, by luminescent down conversion and additive color mixing based on an ultraviolet or blue radiation emitting radiation source. A light-emitting diode as a radiation source is considered in particular.

Recently, various attempts have been made to make white light emitting illumination systems by using visibly colored light emitting diodes as radiation sources. Yet, when generating white light with an arrangement of visibly colored red, green and blue light emitting diodes, there has been such a problem that white light of the desired tone cannot be generated due to variations in the tone, luminance and other factors of visibly colored light emitting diodes.

In order to solve these problems, there have been previously developed various illumination systems, which converted the radiation of UV to blue light emitting diodes by means of a luminescent material comprising a phosphor to provide a white light illumination.

Phosphor converted white light illumination systems have been based in particular either on the trichromatic (RGB) approach, i.e. on mixing three colors, namely red, green and blue, in which case the latter component of the output light may be provided by a phosphor or by the primary emission of the light emitting diode or in a second, simplified solution, on the dichromatic (BY) approach, by mixing yellow and blue colors, in which case the yellow secondary component of the output light may be provided by a yellow phosphor and the blue component may be provided by a phosphor or by the primary emission of a blue light emitting diode.

Yet, it is a general concern with phosphor converted LED lamps using blue to violet-emitting LEDs for excitation of phosphors, that currently known phosphors were not developed and optimized for excitation in this wavelength range.

This leads to a new challenge to be met by phosphors in phosphor converted LEDs.

From US20040227465 a composition of matter useful as a phosphor in light emitting diodes is known, which comprises a material described by the formula: SrₓBa_{y}Ca_{z}SiO₄:Eu in which x, y, and z are each independently any value between 0 and 2, subject to the provision that the sum of x, y, or z is equal to at least 1, and wherein Eu is present in any amount between about 0.0001% and about 5% in mole percent based on the total molar weight of said composition, and wherein at least 50% of all of the europium present is present in the divalent state. In addition, the materials can be manufactured to emit a broad yellowish color, containing both green and red emissions.

From WO2003080763 a tri-color lamp for generating white light is known, comprising a phosphor composition comprising a phosphor of general formula (Ba_{1-x-y-z-}SrₓCa_{y})₂SiO₄:Eu_{z}, wherein 0≦x≦1, 0≦y≦1 and 0≦z≦1. The invention also relates to an alternative to a green LED comprising a single green phosphor of general formula (Ba_{1-x-y-z-}SrₓCa_{y})₂SiO₄:Eu_{z}, wherein 0≦x≦1, 0≦y≦1 and 0≦z≦1, that absorbs radiation from a blue LED. A resulting device provides green light of high absorption efficiency and high luminous equivalent values.

Yet, overall, efficiency and color rendering is a recognized problem with phosphor-converted illumination systems, especially systems comprising light emitting diodes as their radiation source. Longevity of the phosphor is another issue with phosphor-converted light emitting diodes.

### SUMMARY OF THE INVENTION

Thus the present invention provides an illumination system, comprising a radiation source and a luminescent material comprising at least one phosphor capable of absorbing a portion of light emitted by the radiation source and emitting light of a wavelength different from that of the absorbed light; wherein said at least one phosphor is a europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1. Such illumination system provides an efficient and long-life way of illumination.

The efficiency of an illumination system using a source of primary radiation and a phosphor, which converts primary radiation into secondary radiation, is especially dependent on the efficiency of the luminescence conversion process.

A luminescence conversion process in general may be characterized by a number of parameters, including extinction coefficient, excitation, and emission spectrum, Stokes shift, quantum efficiency and lumen efficiency. An extinction coefficient is a wavelength-dependent measure of the absorbing power of a phosphor. An excitation spectrum is the dependence of emission intensity on the excitation wavelength, measured at a single constant emission wavelength. An emission spectrum is the wavelength distribution of the emission, measured after excitation with a single constant excitation wavelength. The term “Stokes shift” is generally defined as the displacement of spectral lines or bands of luminescent radiation to a longer emission wavelength than the excitation lines or bands. Quantum efficiency QE is the ratio of the number of photons emitted to the number of photons absorbed by a phosphor. Inefficient conversion results when at least non-radiative processes consume a portion of the energy.

The illumination system according to the invention may exhibit luminescence with a quantum efficiency that is greater than 110 percent in comparison to the prior art systems. It may also have a lumen efficiency of at least 350 lm/watt. The inventors ascribe this increase in efficiency to the fact that the phosphors according to the invention have an unusually broad continuous and unstructured excitation band in the UVA range of the electromagnetic spectrum extending into the blue to green range. Due to broad continuous excitation spectrum, the phosphors described in the invention have a very small Stokes shift, as the wavelength of exciting radiation is close to the phosphor emission wavelength. They are therefore efficiently excitable with primary radiation in a wavelength range from 200 nm to 500 nm. The quantum loss caused by the conversion of a primary photon emitted by the radiation source into a secondary yellow to red photon is minimized. As a consequence, less of the energy delivered to the lamp is wasted as heat and the luminous efficiency is increased.

This broad excitation spectrum permits the phosphors to be efficiently excited by wavelength-limited light sources, such as common lasers and arc lamps as well as light emitting diodes.

Additional parameters defining an illumination system are the color-rendering index Ra and the color temperature T_{CC}.

The color rendering index (CRI) scale ascertains the quality of the light source, i.e. the relative reproducibility of a certain color under the light source. The higher the CRI, the greater the ease of reproducing a particular color under that light source. An illumination system according to the present invention can provide a composite white output light that is well balanced with respect to color and has a high CRI. In particular, due to the broadband emission of the phosphors the composite white output light has a greater amount of emission in the red and green color range than the conventional illumination system. This characteristic makes the device ideal for applications in which a true color rendering together with high efficiency is required. Such applications of the invention include inter alia traffic lighting, street lighting, security lighting, lighting of automated factories, and signal lighting for cars and traffic.

White-like colors can also be described by a “correlated color temperature” (CCT) in relation to a standard radiation source known as a blackbody radiator. White light produced by an illumination source includes a diverse range of light ranging from warm light to cool light and this diversity is measured by a Color Temperature (CT) scale. In comparison to the prior art phosphors the peak emission wavelength of the present phosphors is shifted to the amber to red range of the electromagnetic spectrum and provides a warm white light sensation.

Especially contemplated as a radiation source for the present invention is a light-emitting diode. The emission produced by a light-emitting diode typically has excellent monochromaticity, because of its narrow spectral half-width of its emission spectrum. Yet, currently available light emitting diodes show strong variations in dominant wavelength, peak wavelength and x/y color coordinates of their narrow-band emission, because the manufacturing process leads to scattering in performance around the average values given in the data sheets.

Therefore, coupling blue or UV-light emitting diodes with conventional phosphors with narrow excitation band leads to binning problems in white LED manufacturing because LEDs differing in wavelength from sample to sample lead to variations in phosphor excitability and thus to white LEDs with widely spread color temperatures and efficiencies.

Coupling blue or UV-light emitting diodes with phosphors of the invention capable of absorbing primary radiation in a broad range of frequencies with equal efficiencies, so as to obtain white light, results in a higher efficiency white solid-state light source.

The better compatibility of the broad band excitation band of the phosphor with the narrow emission maxima of the LEDs permits the light emitting diodes to excite at their emission maximum, rather than at longer wavelengths with lower extinction coefficients.

According to a first aspect of the invention, a white light illumination system comprises a blue-light emitting diode having a peak emission wavelength in the range from 400 to 480 nm as a radiation source and a luminescent material comprising at least one phosphor, that is a europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1

Such an illumination system will provide white light in operation. The blue light emitted by the LED excites the phosphor, causing it to emit yellow, amber or red light. The blue light emitted by the LED is transmitted through the phosphor and is mixed with the yellow to amber or red light emitted by the phosphor. The viewer perceives the mixture of blue and yellow to amber or red light as white light.

An essential factor is that the excitation spectrum of yellow to red phosphors of the europium(II)-activated ortho-phosphosilicate type is so broad-banded in the range from 400 to 480 nm that these phosphors are sufficiently excited by all blue to violet light emitting diodes in the market. As the excitation spectrum of the phosphors according to the invention is centered at 450 nm, blue-LEDs emitting in that wavelength range are preferred.

According to one embodiment of the first aspect, the invention provides a white light illumination system comprising a blue-light emitting diode having a peak emission wavelength in the range from 400 to 480 nm as a radiation source and a luminescent material comprising a europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1 and at least one second phosphor.

When the luminescent material comprises a phosphor blend of a phosphor of the europium(II)-activated ortho-phosphosilicate type and at least one second phosphor, the color rendering of the white light illumination system according to the invention may be further improved.

In particular, the luminescent material of this embodiment may be a phosphor blend, comprising a europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1 and a red phosphor.

Such a red phosphor may be selected from the group of Eu(II)-activated phosphors, comprising (Ca₁₋ₓSrₓ)S:Eu, wherein 0≦x≦1 and (Sr_{1-x-y}BaₓCa_{y})_{2-z}Si₅₋ₐAlₐN₈₋ₐOₐ:Eu_{z} wherein 0≦a≦5, 0≦x≦1, 0≦y≦1 and 0≦z≦1.

Alternatively, the luminescent material may be a phosphor blend, comprising a europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1 and a yellow-to-green phosphor. Such a yellow-to-green phosphor may be selected from the group comprising (Ba₁₋ₓSrₓ)₂SiO₄:Eu, wherein 0≦x≦1, SrGa₂S₄:Eu, SrSi₂N₂O₂:Eu, Ln₃Al₅O₁₂:Ce, wherein Ln comprises lanthanum and all lanthanide metals, and Y₃Al₅O₁₂:Ce.

The emission spectrum of such a luminescent material comprising additional phosphors has the appropriate wavelengths to obtain together with the blue light of the LED and the yellow to red light of the europium(II)-activated ortho-phosphosilicate type phosphor according to the invention a high quality white light with good color rendering at the required color temperature.

According to another embodiment of the invention there is provided a white light illumination system, wherein the radiation source is selected from those light emitting diodes having an emission with a peak emission wavelength in the UV-range from 200 to 400 nm and the luminescent material comprises at least one phosphor, that is a europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1 and a second phosphor.

An essential factor is that the excitation spectrum of yellow to red phosphors of the europium(II)-activated ortho-phosphosilicate type is so broad-banded in the range from 200 to 400 nm, that they are also sufficiently excited by all UV-violet light emitting diodes in the market.

In particular, the luminescent material according to this embodiment may comprise a white light emitting phosphor blend, comprising a europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1 and a blue phosphor.

Such a blue phosphor may be selected from the group comprising BaMgAlₗₒ0₁₇:Eu, Ba₅SiO₄(Cl,Br)₆:Eu, CaLn₂S₄:Ce, wherein Ln comprises lanthanum and the lanthanide metals, and (Sr,Ba,Ca)₅(PO₄)₃Cl:Eu.

A second aspect of the present invention provides an illumination system providing yellow, amber or red light. Applications of the invention include security lighting as well as signal lighting for cars and traffic.

Especially contemplated is a yellow, amber or red light illumination system, wherein the radiation source is selected from those blue light emitting diodes having an emission with a peak emission wavelength in the range from 400 to 480 nm and the luminescent material comprises at least one phosphor, that is a europium(II)-activated ortho-phosphosilicate according to the invention.

Also contemplated is a yellow to red light illumination system, wherein the radiation source is selected from the light emitting diodes having an emission with a peak emission wavelength in the UV-range from 200 to 400 nm and the luminescent material comprises at least one phosphor that is a europium(II)-activated ortho-phosphosilicate of general formula EA_{2-x-y}AₓPₓSi₁₋ₓO₄:Eu_{y} according to the invention.

Another aspect of the present invention provides a phosphor capable of absorbing a portion of the light emitted by the radiation source and emitting light of a wavelength different from that of the absorbed light; wherein said phosphor is a europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1.

The key feature of the phosphor according to the invention is its mixed crystal ortho-phosphosilicate host lattice.

The stable crystal structure of the host lattice is free of non-stoichiometric defects, and is therefore stable with regard to external influence such as heat and ultraviolet to blue radiation. Accordingly, the phosphors according to the invention are highly resistant to photo-bleaching and photo-degradation. Resistance to thermally enhanced photodegradation is of importance as light-emitting diodes under operation can become very hot and any material surrounding the LED will also become hot. The heat can damage a conventional phosphor surrounding the LED, degrading its ability to down-convert the LED's light. The phosphors according to the invention are heat resistant and suited for applications up to 500° C.

The mixed crystal host lattice creates a very broad continuous and unstructured excitation band in the blue and UVA range of the electromagnetic spectrum-enabling the use of a wide range of radiation sources.

The phosphor is excitable by UV radiation, which has such wavelengths as from 200 nm to 400 nm, but is excited with higher efficiency by blue light emitted by a blue light emitting diode having a wavelength around 400 to 480 nm. Thus the phosphor has ideal characteristics for conversion of blue light of nitride semiconductor light emitting component into white light.

These europium(II)-activated ortho-phosphosilicate phosphors emit fast decaying secondary radiation when excited by primary radiation. In comparison to the unsubstituted yellow-green ortho-silicate phosphors of the prior art the emission spectrum is shifted into a broad band with a maximum in the yellow to amber spectral range of the visible spectrum with tails to the green and red range. The visible emission is so broad that there are no 80 nm wavelength ranges where the visible emission is predominantly located.

Additional important characteristics of the phosphors include 1) resistance to thermal quenching of luminescence at typical device operating temperatures (e.g. 80° C.); 2) lack of interfering reactivity with the encapsulating resins used in the device fabrication and moisture; 3) suitable absorptive profiles to minimize dead absorption within the visible spectrum; 4) a temporally stable luminous output over the operating lifetime of the device and; 5) compositionally controlled tuning of the excitation and emission properties of the phosphors.

In particular, the invention relates to specific phosphor composition Sr_{1.372}Ca_{0.588}K_{0.06}Si_{0.94}P_{0.06}O₄:Eu_{0.04} which exhibits a high quantum efficiency of 110 to 150% in comparison to the prior art, high absorbance in the range from 200 nm to 450 nm of 60 to 80%, an emission spectrum with a peak wavelength of about 560 to 640 nm and low losses, i.e. below 10% of the luminescent lumen output due to thermal quenching from room temperature to 150° C.

### BRIEF DESCRIPTION OF THE DRAWINGS

FIG. 1 shows a schematic view of a dichromatic white LED lamp comprising a phosphor of the present invention positioned in a pathway of light emitted by an LED structure.

FIG. 2 shows the emission spectra of Sr_{1.372}Ca_{0.588}K_{0.06}Si_{0.94}P_{0.06}O₄:Eu_{0.04}

FIG. 3 shows the spectral radiance of an illumination system comprising a blue 470 nm LED and Sr_{1.372}Ca_{0.588}K_{0.06}Si_{0.94}P_{0.060}O₄:Eu_{0.04}. as luminescent material in various concentrations.

FIG. 4 shows the spectral radiance of an illumination system comprising a blue 456 nm LED and Sr_{1.372}Ca_{0.588}K_{0.06}Si_{0.94}P_{0.060}O₄:Eu_{0.04} plus (BaSr)_{1.96}SiO₄:Eu_{0.04}. as luminescent material

### DETAILED DESCRIPTION OF EMBODIMENTS

### The Europium(II)-Activated Ortho-Phosphosilicate Phosphor

The present invention focuses on a europium(II)-activated ortho-phosphosilicate as a phosphor in any configuration of an illumination system containing a radiation source, including, but not limited to discharge lamps, luminescent lamps, LEDs, LDs and X-ray tubes.

The luminescent material according to the invention comprises as a phosphor a europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1.

This class of phosphor material is based on europium(II)-activated luminescence of an ortho-phosphosilicate host lattice.

The phosphors according to the invention comprise a host lattice of a crystal type, which can be deduced from the basic beta-K₂SO₄ crystal structure type. The beta-K₂SO₄ structure may be described as an assembly of SO₄²⁻ and K⁺-ions with approximately close-packed O atoms, wherein S is tetrahedrally coordinated by O-atoms and the monovalent metal ions K⁺ occupies two different crystallographically lattice sites with nine-fold and ten-fold coordination by O atoms, respectively. In the isotypic alkaline earth orthosilicates, the monovalent potassium atoms are replaced by divalent alkaline earth atoms and the hexavalent sulfur atoms are replaced by tetravalent silicon atoms. In these orthosilicates the two cation sites M^{I} and M^{II} are surrounded by 5 or 6 complex orthosilicate groups [SiO₄]⁴⁻ leading to complex anions [M^{I}(SiO₄)₅]¹⁸⁻ and [M^{II}(SiO₄)₆]²²⁻ respectively.

In the phosphors according to the invention part of the Si(IV) cations in the lattice sites of the host lattice is replaced by the phosphorous cation P(V). Substitution of Si(IV) by P(V) leads to the creation of charge in the lattice. The charge is compensated by iso-electronic substitution of divalent cations with monovalent cations A.

Owing to the isoelectronic and nearly isosteric replacement of [EA,SiO₄]²⁻ by [A,PO₄]²⁻, which fit together perfectly with regard to size and charge, a series of mixed crystal of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1 can be formed.

“Iso-electronic” in this context is understood to mean having the same valence characteristics as silicate so that the replacement will not electrically affect the stability of the host lattice.

“Iso-steric” in this context means having the same bonding characteristics as silicate so that the replacement will only slightly affect the binding energy of the host lattice.

Preferred as a bivalent cation is strontium. Strontium can be partly substituted by calcium and/or magnesium in an amount up to 10 mol % and can be fully substituted by barium. While incorporation of calcium and magnesium leads to a slight red shift of the emission, the incorporation of barium leads to a blue shift of the emission. Part of the strontium cations may also be substituted by zinc or manganese.

Preferred as the monovalent cation is potassium. Potassium can be partially replaced by sodium and/or rubidium. Part of the potassium may also be substituted by other monovalent cations such as cesium, copper or silver.

The proportion y of europium(II) is preferably in a range of 0.0025≦y≦0.1. When the proportion y of europium(II) is 0.0025 or lower, luminance decreases because the number of excited emission centers of photoluminescence due to europium(II)-cations decreases and, when the y is greater than 0.1, density quenching occurs. Density quenching refers to the decrease in emission intensity, which occurs when the concentration of an activation agent added to increase the luminance of the luminescent material is increased beyond an optimum level.

The method of producing a europium(II)-activated ortho-phosphosilicate phosphor of the present invention is not particularly restricted. It may be produced by any method, capable of providing polycrystalline phosphors according to the invention. A series of compositions of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1 can easily be manufactured, which forms a complete solid solution.

For a preferred process for producing a phosphor according to the invention, phosphor powder particle precursors or phosphor particles are dispersed in slurry, which is then spray-dried to evaporate the liquid. The spray-dried powder is then converted to an ortho-phosphosilicate phosphor by sintering at an elevated temperature in a reducing atmosphere to crystallize the powder and to form the phosphor. The fired powder is lightly crushed and milled to recover phosphor particles of desired particle size.

In a specific embodiment, these yellow to red emitting phosphors are prepared as phosphor powders by the following technique:

Europium(III)-halogenide, alkaline earth carbonate EACO₃, alkaline hydrogen phosphate AH₂PO₄ and silicon oxide are used as the starting materials. Starting materials having a high purity of 99.9% or more and in the form of fine particle having an average particle size of 1 μm or less are preferably used. In the first place, the starting materials are well mixed by a dry and/or wet process utilizing any of various known mixing method such as ball mills, V-shaped mixers, stirrers and the like.

The obtained mixture is placed in a heat-resistant container such as an alumina crucible or a graphite boat, and then calcined in an electric furnace. A preferred temperature for the firing ranges from 1100 to 1400 degree C. With regard to the firing atmosphere it is necessary to conduct firing in a reducing atmosphere such as an atmosphere comprising inert gas such as nitrogen and argon and the like, and hydrogen in a proportion of 0.1 to 10% by volume. The firing period is determined upon various conditions such as the amount of the mixture charged in the container, the firing temperature and the temperature at which the product is taken out of the furnace, but generally in the range from 20 to 24 hours.

Luminescent material obtained by the above-mentioned method may be ground by using, for example, a ball mill, jet mill and the like. Moreover, washing and classification may be conducted. For enhancing the cristallinity of the resulting granular phosphor, re-firing is suggested.

After firing, the powders were characterized by powder X-ray diffraction (Cu, Kα-line), which showed that all compounds had formed.

### Specific Embodiment

A phosphor having a composition Sr_{1.372}Ca_{0.588}K_{0.06}Si_{0.94}P_{0.060}O₄:Eu_{0.04} may be prepared by the following method: 20.850 g SrCO₃ (luminescent grade), 5.944 g CaCO₃ (analytical grade) and 5.684 g SiO₂ (Aerosil OX50) are mixed with an ethanolic solution of EuCl₃*6H₂O (c=0.1512 mmol Eu ml⁻¹, Aldrich) and an aqueous solution of KH₂PO₄ (27.22 mg ml⁻¹, Alfa Aesar Puratronic) with ethanol in an ultrasonic bath for 1 hr. After evaporation of the solvent, the mixture is first calcined at 600° C. for 1 hr in air, then milled, and fired at 1100° C. for 2 hrs in a reducing atmosphere (H₂/N₂ (5/95)). After milling, the powder is fired again at 1150° C. for 2 hrs. The raw phosphor material is then ground and sieved.

The resulting luminescent material is then ground, washed with water and ethanol, dried and sieved. A yellow powder is obtained, which efficiently has luminescence at 595 nm under UV and blue excitation. The color point is at x=0.532 and y=0.462. The lumen equivalent is 357 lm/W.

TABLE 1
Spectroscopic data of (Sr_{1.372}Ca_{0.588})_{1-y}K_{y}Si_{1-y}P_{y}O₄:Eu_{0.04}

| y | rel. QE | RQ (450 nm) | x | y | LE (lm/W) |
|---|---|---|---|---|---|
| 0.02 | 111.6 | 25.4 | 0.529 | 0.462 | 357 |
| 0.04 | 123.0 | 25.3 | 0.53 | 0.461 | 355.8 |
| 0.06 | 152.7 | 26.2 | 0.532 | 0.462 | 357.3 |

Due to the isoelectronic substitution, ortho-phosphosilicates have a different charge distribution and polarity than the corresponding non-substituted silicates. The type and amount of the phosphorous species present in the phosphor compound dictate the local bonding environments of europium(II) in the oxygen-dominant host lattice and determine the characteristics of its emission and absorption spectra.

These europium(II)-activated ortho-phosphosilicate phosphors are responsive to broad energetic portions of the electromagnetic spectrum within the UV- and visible blue portion of the electromagnetic spectrum.

Each phosphor of the europium(II)-activated ortho-phosphosilicate type emits also an extremely broad-banded yellow, amber, or red fluorescence when excited by radiation of the UVA or blue range of the electromagnetic spectrum. In comparison to the prior art the wavelength of maximum emission is shifted to the red range of the electromagnetic spectrum.

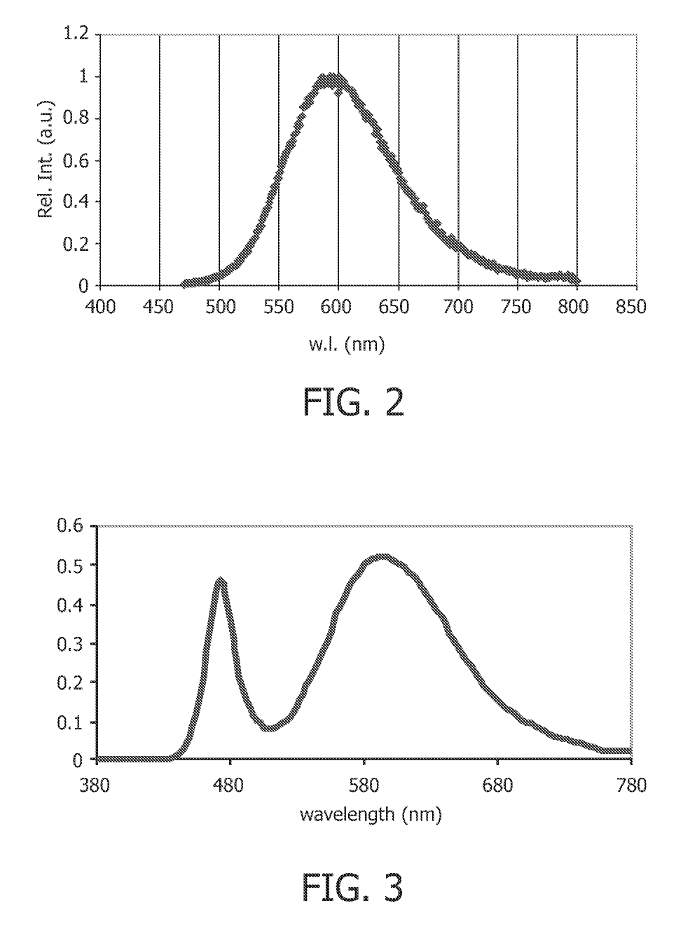

In FIG. 2 of the drawings accompanying this specification, the emission spectra of Sr_{1.372}Ca_{0.588}K_{0.06}Si_{0.94}P_{0.060}O₄:Eu_{0.04} are given. Sr_{1.372}Ca_{0.588}K_{0.06}Si_{0.94}P_{0.06}O₄:Eu_{0.04} has an emission spectrum with a peak wavelength at 590 nm and a tail emission up to 680 nm.

### The Illumination System

The invention also relates to an illumination system comprising a radiation source and a luminescent material comprising at least europium(II)-activated ortho-phosphosilicate of general formula EA_{2-x-y}AₓPₓSi₁₋ₓO₄:Eu_{y} wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1.

As used herein, the term “radiation” encompasses preferably radiation in the UV and visible regions of the electromagnetic spectrum.

Radiation sources include semiconductor optical radiation emitters and other devices that emit optical radiation in response to electrical excitation. Semiconductor optical radiation emitters include light emitting diode LED chips, light emitting polymers (LEPs), organic light emitting devices (OLEDs), polymer light emitting devices (PLEDs), laser diodes (LDs) etc.

Moreover, light-emitting components such as those found in discharge lamps and luminescent lamps, such as mercury low and high pressure discharge lamps, sulfur discharge lamps, and discharge lamps based an molecular radiators are also contemplated for use as radiation sources with the present inventive phosphor compositions.

In a preferred embodiment of the invention the radiation source is a light-emitting diode (LED). It is one of the advantages of the invention that it provides different colors and hues of light sources by using various ratios and types of phosphor blends in an assembly with one or more light emitting diodes.

Any configuration of an illumination system which includes a light emitting diode and a europium(II)-activated ortho-phosphosilicate phosphor composition is contemplated in the present invention, preferably with addition of other well-known phosphors, which can be combined to achieve a specific color or white light when irradiated by a LED emitting primary UV or blue light as specified above.

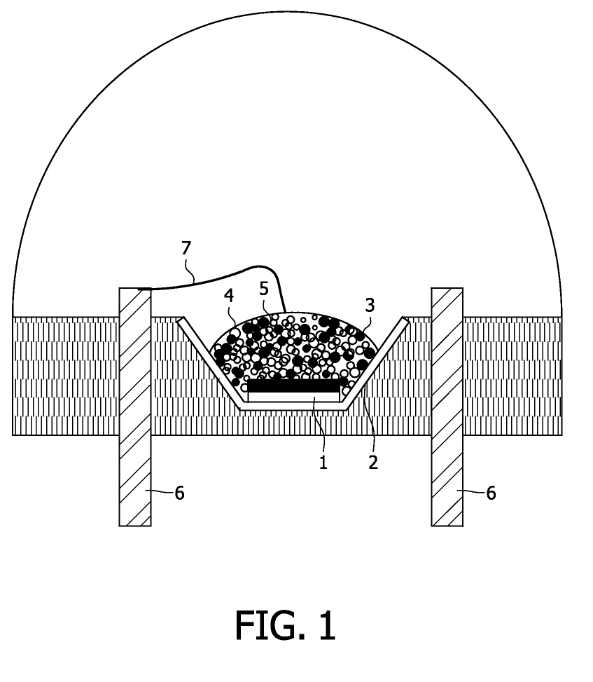

A detailed construction of one embodiment of such illumination system comprising a radiation source and a luminescent material shown in FIG. 1 will now be described.

FIG. 1 is a schematic view of a chip type light emitting diode with a coating comprising the luminescent material. The device comprises chip type light emitting diode 1 as a radiation source. The light-emitting diode dice is positioned in a reflector cup lead frame 2. The dice 1 is connected via a bond wire 7 to a first terminal 6, and directly to a second electric terminal 6′. The recess of the reflector cup is filled with a coating material that contains a luminescent material according to the invention to form a coating layer that is embedded in the reflector cup. The phosphors are applied either separately or in a mixture.

The coating material typically comprises a polymer 5 for encapsulating the phosphor or phosphor blend 3. In this embodiment, the phosphor or phosphor blend should exhibit high stability properties against the encapsulant. Preferably, the polymer is optically clear to prevent any significant light scattering. A variety of polymers are known in the LED industry for making LED illumination systems.

In one embodiment, the polymer is selected from the group consisting of epoxy and silicone resins. Adding the phosphor mixture to a liquid that is a polymer precursor may lead to encapsulation. For example, the phosphor mixture may be a granular powder. Introducing phosphor particles into polymer precursor liquid results in formation of a slurry (i.e. a suspension of particles). Upon polymerization, the phosphor mixture is fixed rigidly in place by the encapsulation. In one embodiment, both the luminescent material and the LED dice are encapsulated in the polymer.

The transparent coating material may comprise light-diffusing particles 4, advantageously so-called diffusers. Examples of such diffusers are mineral fillers, in particular ZrO₂, CaF₂, TiO₂, SiO₂, CaCO₃ or BaSO₄, or organic pigments. These materials can be added in a simple manner to the above-mentioned resins.

In operation, electrical power is supplied to the dice to activate the dice. When activated, the dice emits the primary light, e.g. blue light. A portion of the emitted primary light is completely or partially absorbed by the luminescent material in the coating layer. The luminescent material then emits secondary light, i.e., the converted light having a longer peak wavelength, primarily yellow in a sufficiently broad band (specifically with a significant proportion of red) in response to absorption of the primary light. The remaining unabsorbed portion of the emitted primary light is transmitted through the luminescent layer, along with the secondary light. The encapsulation directs the unabsorbed primary light and the secondary light in a general direction as output light. Thus, the output light is a composite light that is composed of the primary light emitted from the dice and the secondary light emitted from the luminescent layer.

The color temperature or color point of the output light of an illumination system according to the invention will vary depending upon the spectral distributions and intensities of the secondary light in comparison to the primary light.

Firstly, the color temperature or color point of the primary light can be varied by a suitable choice of the light emitting diode.

Secondly, the color temperature or color point of the secondary light can be varied by a suitable choice of the phosphor in the luminescent material, its particle size and its concentration. Furthermore, these arrangements also advantageously afford the possibility of using phosphor blends in the luminescent material, as a result of which, advantageously, the desired hue can be set even more accurately.

### The White Light Phosphor-Converted Light-Emitting Device

According to one aspect of the invention the output light of the illumination system may have a spectral distribution such that it appears to be “white” light.

The most popular white LEDs consist of blue emitting LED chips that are coated with a phosphor that converts some of the blue radiation to a complimentary color, e.g. a yellow to amber emission. The blue and yellow emissions together produce white light.

Then, there are also white LEDs which utilize a UV emitting chip and phosphors designed to convert the UV radiation to visible light. Typically, two or more phosphor emission bands are required.

### Blue/Phosphor White LED

In a first embodiment, a white-light emitting illumination system according to the invention can advantageously be produced by choosing the luminescent material such that a blue radiation emitted by a blue light emitting diode is converted into complementary wavelength ranges, so as to form dichromatic (BY) white light.

In this case, yellow to red light is produced by means of the luminescent materials that comprise a europium(II)-activated ortho-phosphosilicate phosphor. Also a second luminescent material may be used, in addition, in order to improve the color rendering of this illumination system.

Particularly good results are achieved with a blue LED whose emission maximum lies at 400 to 500 nm. An optimum was found to lie at 445 to 468 nm, taking particular account of the excitation spectrum of the europium(I)-activated ortho-phosphosilicate

The color output of the LED-phosphor system is very sensitive to the thickness of the phosphor layer or the amount of phosphor in the phosphor layer respectively. If the phosphor layer is thick and comprises an excess of a yellow to red europium(II)-activated ortho-phosphosilicate phosphor, then a smaller amount of the blue LED light will penetrate through the thick phosphor layer. The combined LED-phosphor system will then in operation appear yellowish to reddish white, because the yellow to red secondary light of the phosphor dominates. Therefore, the thickness of the phosphor layer is a variable, affecting the color output of the system. A large range of flexibility is available both for providing the desired chromaticity and controlling the color output of the individual devices.

In one specific embodiment a white-light emitting illumination system according to the invention can particularly preferably be realized by admixing the inorganic luminescent material Sr_{1.372}Ca_{0.588}K_{0.06}Si_{0.94}P_{0.060}O₄:Eu_{0.04} to a silicon resin used to produce the luminescence conversion encapsulation or layer for a 470 nm InGaN light-emitting diode.

Part of a blue radiation emitted by a 470 nm InGaN light emitting diode is shifted by the inorganic luminescent material Sr_{1.372}Ca_{0.588}K_{0.06}Si_{0.94}P_{0.06}O₄:Eu_{0.04} into the yellow, amber or red spectral region and, consequently, into a wavelength range which is complementarily colored with respect to the color blue. A human observer perceives the combination of blue primary light and the secondary light of the yellow, amber or red-emitting phosphor as white light.

FIG. 3 shows the emission spectra of such an illumination system comprising a blue emitting InGaN dice with primary emission at 470 nm and Sr_{1.372}Ca_{0.588}K_{0.06}Si_{0.94}P_{0.06}O₄:Eu_{0.04} as the luminescent material, which together form an overall spectrum which conveys a warm white color sensation of high quality. The correlated color temperature T_{CC} is measured as 2742 K, the color-rendering index Ra is measured as 71. The deviation from the Black Body Line (BBL) is Δuv=−0.0076

In another embodiment, a white-light emitting illumination system according to the invention can advantageously be produced by choosing the luminescent material such that a blue radiation emitted by the blue light emitting diode is converted into complementary wavelength ranges to form polychromatic, especially trichromatic (RGB) white light. In this case, yellow to red and green light is produced by means of the luminescent materials that comprise a blend of phosphors including a europium(II)-activated ortho-phosphosilicate phosphor and a second phosphor.

A white light emission with high color rendering is made possible by the use of red and green broadband emitter phosphors covering the entire spectral range together with a blue-emitting LED. As a red broadband emitter a yellow to red emitting europium(II)-activated ortho-phosphosilicate phosphor is used.

Useful green and second red phosphors and their optical properties are summarized in the following Table 4.

TABLE 4

| Composition | λₘₐₓ [nm] | Color point x, y |
|---|---|---|
| (Ba₁₋ₓSrₓ)₂SiO₄:Eu | 523 | 0.272, 0.640 |
| SrGa₂S₄:Eu | 535 | 0.270, 0.686 |
| SrSi₂N₂O₂:Eu | 541 | 0.356, 0.606 |
| SrS:Eu | 610 | 0.627, 0.372 |
| (Sr_{1-x-y}CaₓBa_{y})₂Si₅N₈:Eu | 615 | 0.615, 0.384 |
| (Sr_{1-x-y}CaₓBa_{y})₂Si₅₋ₐAlₐN₈₋ₐOₐ:Eu | 615-650 | * |
| CaS:Eu | 655 | 0.700, 0.303 |
| (Sr₁₋ₓCaₓ)S:Eu | 610-655 | * |

The luminescent materials may be a blend of two phosphors, a yellow to red emitting europium(II)-activated ortho-phosphosilicate phosphor and a green phosphor selected from the group comprising (Ba₁₋ₓSrₓ)₂SiO₄:Eu, wherein 0≦x≦1, SrGa₂S₄:Eu and SrSi₂N₂O₂:Eu.

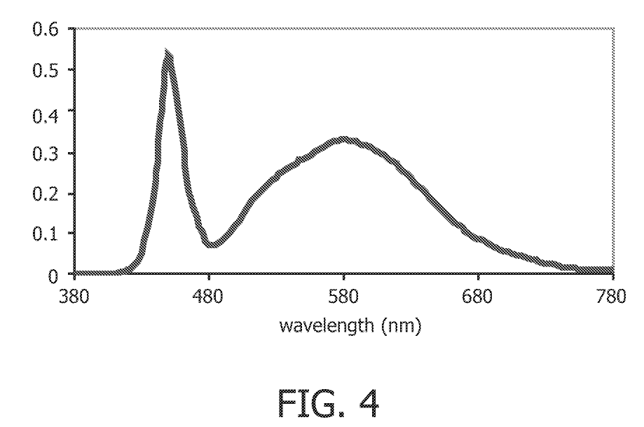

FIG. 4 shows the emission spectrum of a phosphor converted LED comprising a blue emitting InGaN dice with primary emission at 450 nm with two phosphors of composition (a) (Sr_{1.372}Ca_{0.588})_{1-y}K_{y}Si_{1-y}P_{y}O₄:Eu_{0.04} for y=0.06 and (b) (BaSr)_{1.96}SiO₄:Eu_{0.04}. T_{CC} was measured as 4438 K, Ra=80, Δuv=−0.0077.

The hue (color point in the CIE chromaticity diagram) of the white light thus produced can be varied in this embodiment by a suitable choice of the phosphors as regards their mixture and concentration.

### UV/Phosphor White LED

In another embodiment, a white-light emitting illumination system according to the invention can advantageously be produced by choosing the luminescent material such that a UV radiation emitted by the UV light emitting diode is converted into complementary wavelength ranges, to form dichromatic white light. In this case, the yellow and blue light is produced by means of the luminescent materials. Yellow to red light is produced by means of the luminescent materials that comprise a europium(II)-activated ortho-phosphosilicate phosphor. Blue light is produced by means of the luminescent materials that comprise a blue phosphor selected from the group comprising BaMgAlₗₒ0₁₇:Eu, Ba₅SiO₄(Cl,Br)₆:Eu, CaLn₂S₄:Ce and (Sr,Ba,Ca)₅(PO₄)₃Cl:Eu.

Particularly good results are achieved using a UVA light emitting diode, whose emission maximum lies at 300 to 400 nm. An optimum was found to lie at 365 nm, taking particular account of the excitation spectrum of the europium(II)-activated ortho-phosphosilicate

In another specific embodiment, a white-light emitting illumination system according to the invention can advantageously be produced by choosing the luminescent material such that UV radiation emitted by a UV emitting diode is converted into complementary wavelength ranges, so as to form polychromatic white light e.g. by additive color triads, for example blue, green and red.

In this case, the yellow to red, the green and blue light is produced by means of the luminescent materials.

A white light emission with especially high color rendering is possible by using blue and green broadband emitter phosphors, covering the whole spectral range, together with a UV emitting LED and a yellow to red emitting europium(II)-activated ortho-phosphosilicate phosphor.

The luminescent materials may be a blend of a yellow to red europium(II)-activated ortho-phosphosilicate phosphor, a blue phosphor selected from the group comprising BaMgAl₁₀0₁₇:Eu, Ba₅SiO₄(Cl,Br)₆:Eu, CaLn₂S₄:Ce and (Sr,Ba,Ca)₅(PO₄)₃Cl:Eu and a green phosphor selected from the group comprising (Ba₁₋ₓSrₓ)₂SiO₄:Eu, wherein 0≦x≦1, SrGa₂S₄:Eu and SrSi₂N₂O₂:Eu. A second red luminescent material can be used, in addition, to improve the color rendering of this illumination system.

The hue (color point in the CIE chromaticity diagram) of the white light thereby produced can in this case be varied by a suitable choice of the phosphors as regards mixture and concentration.

### The Yellow to Red Phosphor Converted Light Emitting Device

A further aspect of the invention relates to an illumination system that emits output light having a spectral distribution such that it appears to be “yellow to red” light.

A luminescent material comprising europium(II)-activated ortho-phosphosilicate as phosphor is particularly well suited as a yellow to red component for stimulation by a primary UVA or blue radiation source such as, for example, a UVA-emitting LED or blue-emitting LED. It is possible thereby to implement an illumination system emitting in the yellow to red regions of the electromagnetic spectrum.

In one embodiment of this aspect of the invention, a yellow-light emitting illumination system can advantageously be produced by choosing the luminescent material such that a blue radiation emitted by the blue light emitting diode is converted into complementary wavelength ranges, so as to form dichromatic yellow light.

In this case, yellow light is produced by the luminescent materials that comprise a phosphor.

The color output of the LED phosphor system is very sensitive to the thickness of the phosphor layer, if the phosphor layer is thick and comprises an excess of a yellow europium(II)-activated ortho-phosphosilicate phosphor, then a smaller amount of the blue LED light will penetrate through the thick phosphor layer. The combined LED phosphor system will then appear yellow to red, because the yellow to red secondary light of the phosphor dominates it. Therefore, the thickness of the phosphor layer is a variable affecting the color output of the system.

The hue (color point in the CIE chromaticity diagram) of the yellow light thereby produced can in this case be varied by a suitable choice of the phosphor as regards mixture and concentration.

In a further embodiment of this aspect of the invention, choosing the luminescent material such that a UV radiation emitted by the UV emitting diode is converted entirely into monochromatic yellow to red light can advantageously produce a yellow to red light emitting illumination system according to the invention. In this case, the yellow to red light is produced by means of the luminescent materials.

The hue (color point in the CIE chromaticity diagram) of the white light thus produced can be varied by a suitable choice of the phosphor as regards mixture and concentration.

1. Illumination system, comprising a radiation source and a luminescent material comprising at least one phosphor capable of absorbing a portion of light emitted by the radiation source and emitting light of a wavelength different from that of the absorbed light; wherein said at least one phosphor is a europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1.

2. Illumination system according to claim 1, wherein the radiation source is a light-emitting diode.

3. Illumination system according to claim 2, wherein the radiation source is selected from those light emitting diodes having an emission with a peak emission wavelength in the range from 400 to 480 nm.

4. Illumination system according to claim 2, wherein the luminescent material comprises a second phosphor.

5. Illumination system according to claim 4, wherein said second phosphor is a red phosphor selected from the group of (Ca₁₋ₓSrₓ)S:Eu, wherein 0≦x≦1 and
(Sr_{1-x-y}BaₓCa_{y})_{2-z}Si₅₋ₐAlₐN₈₋ₐOₐ:Eu_{z} wherein 0≦a≦5.0≦x≦1, 0≦y≦1 and
0≦z≦0.1.

6. Illumination system according to claim 4, wherein the second phosphor is a yellow to green phosphor selected from the group comprising (Ba₁₋ₓSrₓ)₂SiO₄:Eu, wherein 0≦x≦1, SrGa₂S₄:Eu, SrSi₂N₂O₂:Eu, Ln₃Al₅O₁₂:Ce and YAG:CE³⁺.

7. Illumination system according to claim 2, wherein the radiation source is selected from those light emitting diodes having an emission with a peak emission wavelength in the UV range from 200 to 400 nm.

8. Illumination system according to claim 7, wherein the luminescent material comprises a second phosphor.

9. Illumination system according to claim 8, wherein said second phosphor is a blue phosphor selected from the group of BaMgAlₗₒ0₁₇:Eu, Ba₅SiO₄(Cl,Br)₆:Eu, CaLn₂S₄:Ce, (Sr,Ba,Ca)₅(PO₄)₃Cl:Eu and LaSi₃N₅:Ce.

10. Illumination system according to claim 8, wherein the second phosphor is a red phosphor selected from the group of (Ca₁₋ₓSrₓ)S:Eu, wherein 0≦x≦1 and
(Sr_{1-x-y}BaₓCa_{y})_{2-z}Si₅₋ₐAlₐN₈₋ₐOₐ:Eu_{z} wherein 0≦a<5.00<x≦1, 0<y≦1 and 0<z≦0.1.

11. Illumination system according to claim 8, wherein the second phosphor is a yellow to green phosphor selected from the group comprising (Ba₁₋ₓSrₓ)₂SiO₄:Eu, wherein 0≦x≦1, SrGa₂S₄:Eu, SrSi₂N₂O₂:Eu, Ln₃Al₅O₁₂:Ce and YAG:Ce³⁺.

12. Phosphor capable of absorbing part of light emitted by a radiation source and emitting light of a wavelength different from that of the absorbed light; wherein said phosphor is a europium(II)-activated ortho-phosphosilicate of general formula EA_{2-x-y}AₓPₓSi₁₋ₓO₄:Eu_{y}, wherein EA is at least one bivalent metal selected from the group comprising calcium, magnesium, strontium, barium, zinc and manganese, A is at least one monovalent metal chosen from the group of lithium, sodium, potassium, rubidium, cesium, copper and silver, and wherein 0.01≦x≦1 and 0.0025≦y≦0.1.

13. Phosphor according to claim 12, wherein said phosphor is a europium(II)-activated ortho-phosphosilicate of general formula Sr_{1.372}Ca_{0.588}K_{0.06}Si_{0.94}P_{0.06}O₄:Eu_{0.04}
